(19) United States
(12) Patent Application Publication
(10) Pub. No.: US 2026/0020242 A1
(43) Pub. Date: Jan. 15, 2026

(54) MICROELECTRONIC DEVICES INCLUDING SHAPE MEMORY MATERIALS, AND RELATED METHODS, MEMORY DEVICES, AND ELECTRONIC SYSTEMS

(71) Applicant: Micron Technology, Inc., Boise, ID (US)

(72) Inventors: Srinivasa Reddy Yeduru, Meridian, ID (US); Swapnil A. Lengade, Boise, ID (US)

(21) Appl. No.: 19/237,780

(22) Filed: Jun. 13, 2025

Related U.S. Application Data
(60) Provisional application No. 63/671,397, filed on Jul. 15, 2024.

(51) Int. Cl. H10B 43/35; H10B 43/27

(52) U.S. Cl. CPC H10B 43/35; H10B 43/27

(57) ABSTRACT

A microelectronic device includes a stack structure having tiers vertically stacked relative to one another, and pillar structures respectively including semiconductor material vertically extending through the tiers of the stack structure. The tiers of the stack structure respectively include insulative material, shape memory material vertically neighboring the insulative material, and conductive material vertically neighboring the shape memory material. Methods of forming a microelectronic device structure are also described.

### PRIORITY CLAIM

This application claims the benefit of the filing date of U.S. Provisional Patent Application Ser. No. 63/671,397, filed Jul. 15, 2024, for “MICROELECTRONIC DEVICES INCLUDING SHAPE MEMORY MATERIALS, AND RELATED METHODS, MEMORY DEVICES, AND ELECTRONIC SYSTEMS,” the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier and less expensive to fabricate designs.

One example of a microelectronic device is a memory device. Memory devices are generally provided as internal integrated circuits in computers or other electronic devices. There are many types of memory devices including, but not limited to, non-volatile memory (NVM) devices, such as flash memory devices (e.g., NAND flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including structures of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

However, the manufacturing of 3D NAND flash memory arrays presents significant challenges, particularly with respect to tier deflection and stiction. Tier deflection refers to the undesired deviation of individual tiers from their intended positions during the fabrication process. This phenomenon can arise due to various factors, including stress induced by the deposition of subsequent layers, thermal processing steps, and mechanical forces encountered during the manufacturing operations. Tier deflection can lead to several detrimental effects on the performance and reliability of the memory devices. Firstly, misalignment of the tiers can result in difficulties in properly aligning subsequent layers, potentially causing electrical shorts or open circuits within the memory array. Secondly, tier deflection can introduce mechanical stress and strain within the memory structure, affecting the endurance and reliability of the memory cells. Additionally, variations in the effective channel lengths of the memory cells due to tier deflection can lead to non-uniform electrical characteristics and performance across the array.

Another significant issue frequently encountered in conventional 3D NAND flash memory manufacturing processes is stiction, in relation to undesired adhesion or sticking of adjacent tiers or layers within the memory stack. Stiction can occur due to various factors, including capillary forces, van der Waals forces, and electrostatic interactions between the materials of the tier during the manufacturing process. Stiction can have negative consequences for the memory array, potentially causing mechanical deformation, shorting of adjacent conductors, and/or failure of the memory device.

Both tier deflection and stiction can lead to significant yield losses and increased manufacturing costs, as affected memory arrays may need to be discarded or undergo complex and costly rework processes.

### BRIEF DESCRIPTION OF THE DRAWINGS

FIGS. 1 through 4B are simplified, partial vertical cross-sectional views illustrating a method of forming a microelectronic device, in accordance with embodiments of the disclosure.

FIGS. 5 through 7 are simplified, partial vertical cross-sectional views illustrating a method of forming a microelectronic device, in accordance with additional embodiments of the disclosure.

FIGS. 8 through 11 are simplified, partial vertical cross-sectional views illustrating a method of forming a microelectronic device, in accordance with further embodiments of the disclosure.

FIG. 12 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the term “substantially” in reference to a given parameter, property, or condition means and includes to a degree that one skilled in the art would understand that the given parameter, property, or condition is met with a small degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 106.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})).

As used herein, the term “semiconductor material” refers to a material having an electrical conductivity between those of insulative materials and conductive materials. For example, a semiconductor material may have an electrical conductivity of between about 10⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

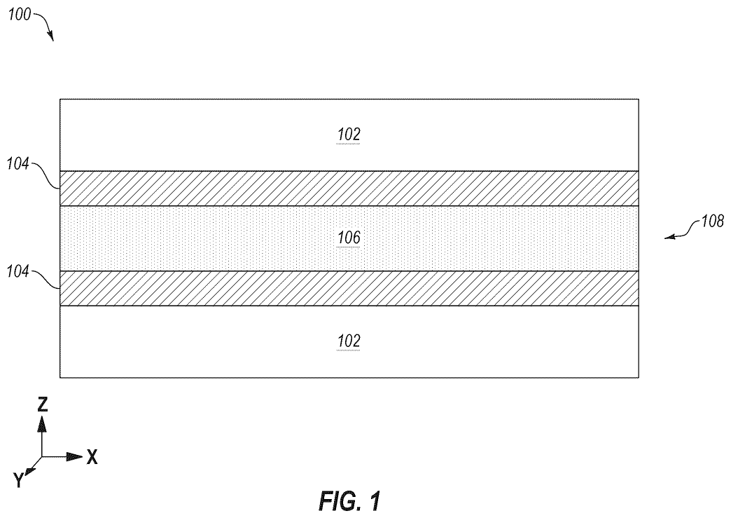

FIGS. 1 through 3B are simplified, partial vertical cross-sectional views illustrating embodiments of a method of forming a microelectronic device (e.g., a memory device, such as a non-volatile memory device or a volatile memory device). With the description provided below, it will be readily apparent to one of ordinary skill in the art that the methods and structures described herein may be used in various devices and electronic systems.

Referring to FIG. 1, a microelectronic device structure 100 for a microelectronic device may initially be formed to include, without limitation, a preliminary stack structure 108. The preliminary stack structure 108 may include insulative material 102, shape memory material 104, and sacrificial material 106 at different vertical positions than one another.

As shown in FIG. 1, a portion of the microelectronic device structure 100 may include a level (e.g., tier) of the insulative material 102, a level of the shape memory material 104 on or over the level of the insulative material 102, a level of the sacrificial material 106 on or over the level of the shape memory material 104, an additional level of the shape memory material 104 on or over the level of the sacrificial material 106, and an additional level of the insulative material 102 on or over the additional level of the shape memory material 104. Put another way, the microelectronic device structure 100 may be formed such that an individual level of the sacrificial material 106 is vertically interposed between two (2) levels of the shape memory material 104, and such that the two (2) levels of the shape memory material 104 are vertically interposed between two (2) levels of the insulative material 102. While FIG. 1 only shows a portion of the microelectronic device structure 100, it will be understood that such an arrangement of levels of the insulative material 102, the shape memory material 104, and the sacrificial material 106 may be repeated across a desired vertical height (e.g., in the Z-direction) of the microelectronic device structure 100.

The insulative material 102 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). The levels of the insulative material 102 may all have substantially the same material composition as one another, or at least one level of the insulative material 102 may have a different material composition than at least one other level of the insulative material 102. In addition, the levels of the insulative material 102 may respectively be substantially homogeneous or heterogeneous. In some embodiments, each of the levels of the insulative material 102 is formed of and includes a dielectric oxide material, such as SiOₓ (e.g., SiO₂).

The shape memory material 104 may be formed of and include one or more of at least one shape memory oxide material (e.g., one or more of VO₂, VMoO₂, VWO₂), at least one shape memory ceramic material (e.g., one or more of BiFeO₃, BaTiO₃, CeO₂—ZrO₂, CeO₂—Y₂O₃, CeO₂—ZrO₂), and at least one shape memory alloy material (e.g., CuAlNi alloy, NiTi alloy). The levels of the shape memory material 104 may all have substantially the same material composition as one another, or at least one level of the shape memory material 104 may have a different material composition than at least one other level of the shape memory material 104. In some embodiments, each of the levels of the shape memory material 104 is formed of and includes a shape memory oxide material, such as VO₂. The levels of the shape memory material 104 may respectively be doped with one or more chemical species (e.g., one or more dopants). A concentration of the dopant with an individual level of the shape memory material 104 may be less than or equal to about 5% by weight of the individual level of the shape memory material 104, such as within a range of from about 0% to about 1% by weight, from about 1% to about 2% by weight, from about 2% to about 3% by weight, from about 3% to about 4% by weight, or from about 4% to about 5% by weight. Non-limiting examples of suitable dopants for the shape memory material 104 include one or more of molybdenum and tungsten. The levels of the shape memory material 104 may respectively be substantially homogeneous or heterogeneous. Each level of the shape memory material 104 may have a thickness (i.e., a vertical height) of less than or equal to about 10% of a thickness of an individual level of the insulative material 102.

The shape memory material 104 may be formed using conventional processes (e.g., conventional deposition processes), which are not described in detail herein. By way of non-limiting example, the shape memory material 104 may be formed by way of one or more of a conventional chemical vapor deposition (CVD) process (e.g., a conventional plasma-enhanced CVD (PECVD) process) and a conventional atomic layer deposition (ALD) process. In some embodiments, an individual level of the shape memory material 104 is formed on an individual level of the insulative material 102 using a PECVD process.

The levels of the shape memory material 104 (e.g., insulative shape memory material) may prevent undesirable bending of the levels of insulative material 102 during later stages of processing by changing shape in response to a change in temperature. For example, levels of the shape memory material 104 may contract at high temperatures and elongate at low temperatures to adjust (e.g., pull) levels of the insulative material 102 of the preliminary stack structure 108 back to their original shapes. The levels of the shape memory material 104 may also increase rigidity of the preliminary stack structure 108, which may help maintain its overall shape when levels of the sacrificial material 106 are subsequently removed (e.g., during subsequent replacement gate processing). Maintaining the shape of the respective levels of insulative material 102 when respective levels of the sacrificial material 106 are removed may substantially prevent undesirable tier collapse during and/or after the removal process.

The sacrificial material 106 of the preliminary stack structure 108 may be formed of and include at least one material (e.g., at least one insulative material) that may be selectively removed relative to the insulative material 102 and the shape memory material 104. A material composition of the sacrificial material 106 is different than a material compositions of the insulative material 102 and the shape memory material 104. The sacrificial material 106 may be selectively etchable relative to the insulative material 102 and the shape memory material 104 during common (e.g., collective, mutual) exposure to an etchant insulative material 102. As used herein, a material is “selectively etchable” relative to another material if the material exhibits an etch rate that is at least about three times (3x) greater than the etch rate of another material, such as about five times (5x) greater, such as about ten times (10x) greater, about twenty times (20x) greater, or about forty times (40x) greater. As a non-limiting example, the sacrificial material 106 may be formed of and include insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). The levels of the sacrificial material 106 may all have substantially the same material composition as one another, or at least one level of the sacrificial material 106 may have a different material composition than at least one other level of the sacrificial material 106. In addition, the levels of the sacrificial material 106 may respectively be substantially homogeneous or heterogeneous. In some embodiments, each of the levels of the sacrificial material 106 is formed of and includes a dielectric nitride material, such as SiN_{y} (e.g., Si₃N₄). The sacrificial material 106 may be substantially homogeneous or substantially heterogeneous.

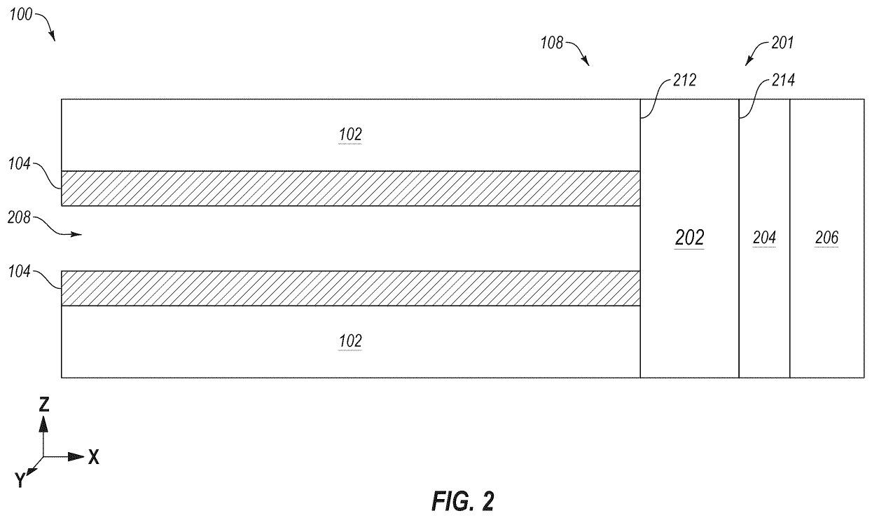

Referring next to FIG. 2, cell pillar structures 201 may be formed to vertically extend through the preliminary stack structure 108, and then the levels of the sacrificial material 106 (FIG. 1) may be selectively removed to form cavities 208 (e.g., void spaces). The cell pillar structures 201 may respectively include blocking dielectric material 202, a charge storage material 204 (e.g., charge trapping material), and additional materials 206 (e.g., tunnel dielectric material, channel material, additional dielectric material). For an individual cell pillar structure 201, the blocking dielectric material 202 may be formed on or over sidewalls 212 of the preliminary stack structure 108, the charge storage material 204 may be formed on or over inner sidewalls 214 of the blocking dielectric material 202, and the additional materials 206 may be formed on or over inner sidewalls of the charge storage material 204.

As shown in FIG. 2, the blocking dielectric material 202 of an individual cell pillar structure 201 may be formed to have an outer sidewall 218 directly horizontally adjacent a sidewall 212 (e.g., side surface) of the preliminary stack structure 108. In some embodiments, the outer sidewall 218 of the blocking dielectric material 202 has a substantially linear vertical profile. The blocking dielectric material 202 may have a substantially uniform horizontal thickness throughout a vertical height thereof. The blocking dielectric material 202 may be formed of and include an insulative material, such as at least one dielectric oxide material (e.g., SiOₓ, such as SiO₂). The blocking dielectric material 202 may be configured to prevent shorts between subsequently formed (e.g., following replacement gate processing) levels of conductive material at a horizontal position of the sidewall 212.

The charge storage material 204 of an individual cell pillar structure 201 may be formed (e.g., conformally formed) on or over the inner sidewalls 214 of blocking dielectric material 202. The charge storage material 204 may be formed of and include additional insulative material, such as a dielectric nitride material (e.g., SiN_{y}, such as Si₃N₄). The charge storage material 204 may substantially conform to the inner sidewalls 214 of the blocking dielectric material 202.

The additional materials 206 of an individual cell pillar structure 201 may include a tunnel dielectric material (e.g., dielectric oxide material) formed on or over inner sidewalls of the charge storage material 204, and a channel material (e.g., semiconductor material) formed on or over inner sidewalls of the tunnel dielectric material. The additional materials 206 may also include other materials, such as a dielectric fill material (e.g., additional dielectric oxide material) on or over inner sidewalls of the tunnel channel material.

In some embodiments, the cell pillar structures 201 are configured to facilitate the formation of memory cells at intersections of subsequently formed (e.g., following replacement gate processing) levels of conductive material and the cell pillar structures 201, such as so-called “MONOS” (metal-oxide-nitride-oxide-semiconductor) memory cells, so-called “TANOS” (tantalum nitride-aluminum oxide-nitride-oxide-semiconductor) memory cells, or so-called “BETANOS” (band/barrier engineered TANOS) memory cells. TANOS memory cells and BETANOS memory cells are subsets of MONOS memory cells.

After forming the cell pillar structures 201, the sacrificial material 106 (FIG. 1) at different levels of the sacrificial material 106 (FIG. 1) may be selectively removed to form the cavities 208. For an individual level of the sacrificial material 106, the sacrificial material 106 thereof may be at least partially (e.g., substantially) removed through a selective etching process, such as a wet etching process employing one or more wet etchants (e.g., phosphoric acid (H₃PO₄)) selected to etch the sacrificial material 106 faster than the insulative material 102 and the shape memory material 104. When an individual level of the sacrificial material 106 is removed, an individual cavity 208 may be formed vertically between the vertically neighboring levels of the shape memory material 104.

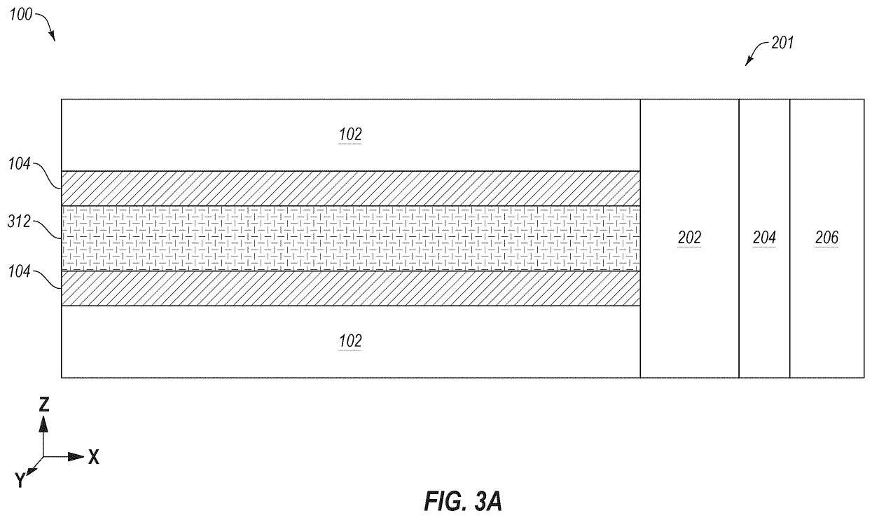

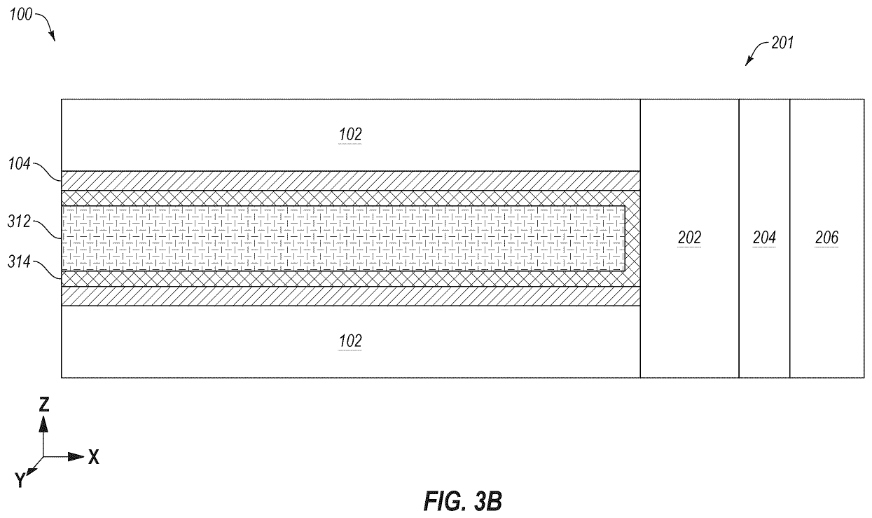

Referring next to FIG. 3A, the cavities 208 (FIG. 2) may respectively be filled with conductive material 312. Accordingly, the levels of the sacrificial material 106 (FIG. 1) may be replaced with levels of the conductive material 312. The conductive material 312 may comprise, for example, one or more of at least one metal, at least one metal alloy, at least one conductive metal oxide, at least one conductive metal nitride, at least one conductive metal silicide, and at least one conductively doped semiconductor material. By way of non-limiting example, the conductive material 312 may be formed of and include one or more of tungsten (W), tungsten nitride (WN), nickel (Ni), tantalum (Ta), tantalum nitride (TaNₓ), tantalum silicide (TaSi), platinum (Pt), copper (Cu), silver (Ag), gold (Au), aluminum (Al), molybdenum (Mo), titanium (Ti), titanium nitride (TiNₓ), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrOₓ), ruthenium (Ru), ruthenium oxide (RuOₓ), and conductively-doped silicon. The levels of the conductive material 312 may all have substantially the same material composition as one another, or at least one level of the conductive material 312 may have a different material composition than at least one other level of the conductive material 312. In some embodiments, each of the levels of the conductive material 312 is formed of and includes Mo. In additional embodiments, each of the levels of the conductive material 312 is formed of and includes W. In further embodiment embodiments, each of the levels of the conductive material 312 is formed of and includes TiNₓ. In further embodiments, each of the levels of the conductive material 312 is formed of and include a metallic material including one or more of fluorine (F) and chlorine (Cl).

For an individual level of the conductive material 312, the conductive material 312 may extend to the outer sidewall 218 of the blocking dielectric material 202. The conductive material 312 may be vertically interposed between (e.g., vertically extend from and between) the shape memory material 104 of two (2) levels of the shape memory material 104. In some embodiments, the level of the conductive material 312 is employed as local access lines (e.g., local word lines) for a microelectronic device (e.g., memory device) of the disclosure.

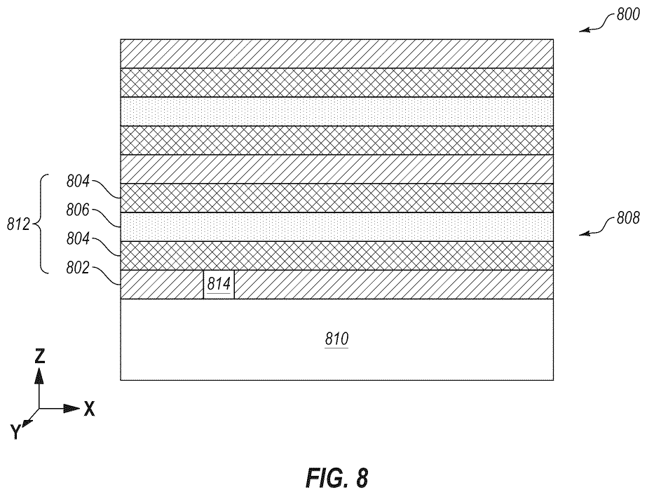

With reference to FIG. 3B, in additional embodiments, liner material 314 is formed within respective cavities 208 (FIG. 2) before forming the conductive material 312 within the cavities 208. For an individual cavity 208 (FIG. 2), the liner material 314 may be formed to partially (e.g., less than completely) fill the cavity 208 (FIG. 8), and then the conductive material 312 may be formed to substantially fill a remainder of the cavity 208 (FIG. 2). Within an individual cavity 208 (FIG. 2), the liner material 314 may be formed on or over the exposed surfaces of the shape memory material 104 and blocking dielectric material 202. The liner material 314 may, for example, be formed of and include one or more of a metal (e.g., titanium, tantalum), an alloy, a metal nitride (e.g., tungsten nitride, titanium nitride, tantalum nitride), and a metal oxide (e.g., aluminum oxide). In some embodiments, the liner material 314 includes aluminum oxide. In additional embodiments, the liner material 314 may also be formed of and include at least one additional shape memory material, such as one or more of at least one shape memory oxide material (e.g., one or more of VO₂, VMoO₂, VWO₂), at least one shape memory ceramic material (e.g., one or more of BiFeO₃, BaTiO₃, CeO₂—ZrO₂, CeO₂—Y₂O₃, CeO₂—ZrO₂), and at least one shape memory alloy material (e.g., one or more of CuAlNi alloy and NiTi alloy). In some embodiments, the liner material 314 is formed of and includes Al₂O₃. In additional embodiments, the liner material 314 is formed of and includes shape memory oxide material, such as VO₂. In further embodiments, the liner material 314 is formed of and includes a doped form of a shape memory oxide material, such as VMoO₂ or VWO₂.

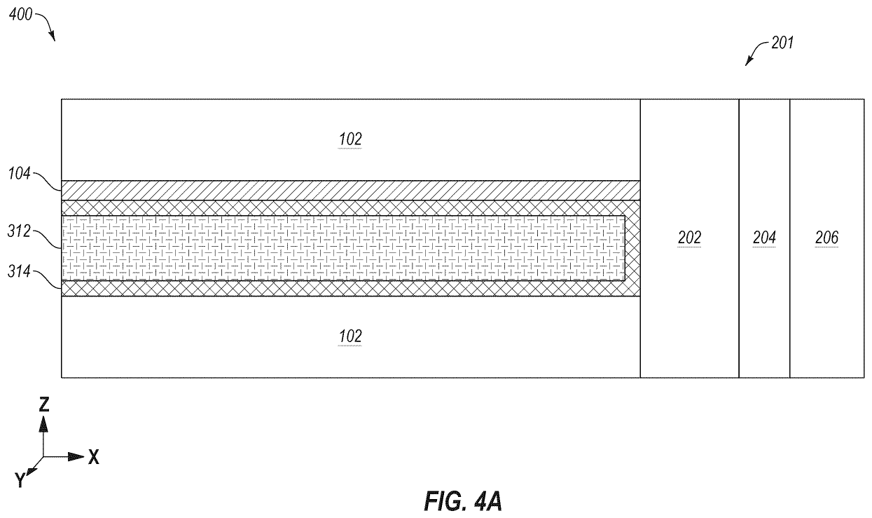

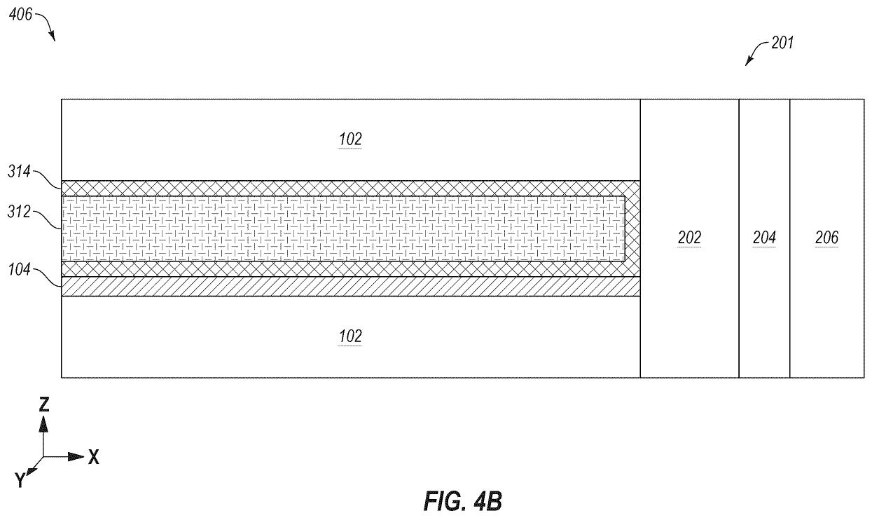

In additional embodiments, one or more of the processing acts previously described with respect to one of more of FIGS. 1 through 3B may be modified, resulting in changes to one of more of the features (e.g., materials, structures) previously described with reference to one or more of FIGS. 1 through 3B. For example, FIGS. 4A and 4B illustrate a microelectronic device structure 400 (FIG. 4A) and a microelectronic device structure 406 (FIG. 4B), each having a different configuration than the microelectronic device structure 100 at the processing stage previously described with reference to FIGS. 3A and 3B. To avoid repetition, not all features shown in FIGS. 4A and 4B are described in detail below. Rather, unless described otherwise, in FIGS. 4A and 4B, a feature designated by a reference numeral that is the same as the reference numeral of a previously described feature will be understood to be substantially similar to and formed in substantially the same manner as the previously described feature.

Referring collectively to FIG. 4A and FIG. 4B, in additional embodiments, the preliminary stack structure 108 previously described with reference to FIG. 1 is formed such that one level of the shape memory material 104 is formed vertically adjacent to an individual level of the sacrificial material 106 (FIG. 1). For example, for an individual level of the sacrificial material 106 (FIG. 1), a level of the shape memory material 104 may be formed vertically below and adjacent to the level of the sacrificial material 106, but another level of the shape memory material 104 may not be formed vertically above and adjacent to the level of the sacrificial material 106. FIG. 4A illustrates the microelectronic device structure 400 that may result from this modification, wherein following replacement of a level of the sacrificial material 106 (FIG. 1) with a level of the conductive material 312 and, optionally, a level of the liner material 314, a level of the shape memory material 104 vertically overlies and physically contacts an upper portion of the level of the liner material 314 (or the level of the conductive material 312 if the level of liner material 314 is omitted), but a level of the insulative material 102 vertically underlies and physically contacts a lower portion of the level of the liner material 314 (or the level of the conductive material 312 if the liner material 314 is omitted). As another example, for an individual level of the sacrificial material 106 (FIG. 1), a level of the shape memory material 104 may be formed vertically above and adjacent to the level of the sacrificial material 106, but another level of the shape memory material 104 may not be formed vertically below and adjacent to the level of the sacrificial material 106. FIG. 4B illustrates a microelectronic device structure 406 that may result from this modification, wherein following replacement of a level of the sacrificial material 106 (FIG. 1) with a level of the conductive material 312 and, optionally, a level of the liner material 314, a level of the shape memory material 104 vertically underlies and physically contacts a lower portion of the level of the liner material 314 (or the level of the conductive material 312 if the level of liner material 314 is omitted), but a level of the insulative material 102 vertically overlies and physically contacts an upper portion of the level of the liner material 314 (or the level of the conductive material 312 if the liner material 314 is omitted).

Thus, in accordance with embodiments of the disclosure, a method of forming a microelectronic device includes forming a preliminary stack structure having tiers vertically stacked relative to one another and respectively including insulative material, shape memory material vertically neighboring the insulative material, and sacrificial material vertically neighboring the shape memory material. Pillar structures respectively including semiconductor material are formed to vertically extend through the tiers of the preliminary stack structure. The sacrificial material of the tiers of the preliminary stack structure are replaced with conductive material after forming the pillar structures.

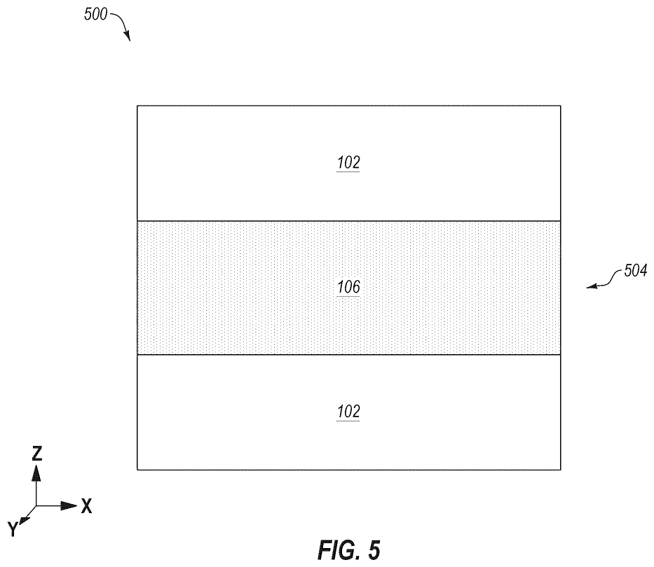

In additional embodiments, the method of forming a microelectronic device previously described with reference to FIGS. 1 through 3B may be modified by proponing (e.g., delaying) the formation of the levels of the shape memory material 104 relative to when the levels of the shape memory material 104 are formed in the method described with reference to FIGS. 1 through 3B. For example, FIGS. 5 through 7 are simplified, partial vertical cross-sectional views illustrating a method of forming a microelectronic device (e.g., a memory device, such as a non-volatile memory device or a volatile memory device), in accordance with additional embodiments of the disclosure. With the description provided below, it will be readily apparent to one of ordinary skill in the art that the methods and structures described herein may be used in various devices and electronic systems.

Referring to FIG. 5, a microelectronic device structure 500 for a microelectronic device may initially be formed to include, without limitation, a preliminary stack structure 504. The preliminary stack structure 504 may include the insulative material 102 and the sacrificial material 106 previously described herein with reference to FIGS. 1-3B, but may initially be free of the shape memory material 104 (FIGS. 1 through 3B). For example, as shown in FIG. 5, a portion of the microelectronic device structure 500 may include a level (e.g., tier) of the insulative material 102, a level of the sacrificial material 106 on or over the level of the insulative material 102, and an additional level of the insulative material 102 on or over the level of the sacrificial material 106. The microelectronic device structure 500 may be formed such that an individual level of the sacrificial material 106 vertically extends from and between two (2) levels of the insulative material 102. While FIG. 5 only shows a portion of the microelectronic device structure 500, it will be understood that such an arrangement of levels of the insulative material 102 and the sacrificial material 106 may be repeated across a desired vertical height (e.g., in the Z-direction) of the microelectronic device structure 500.

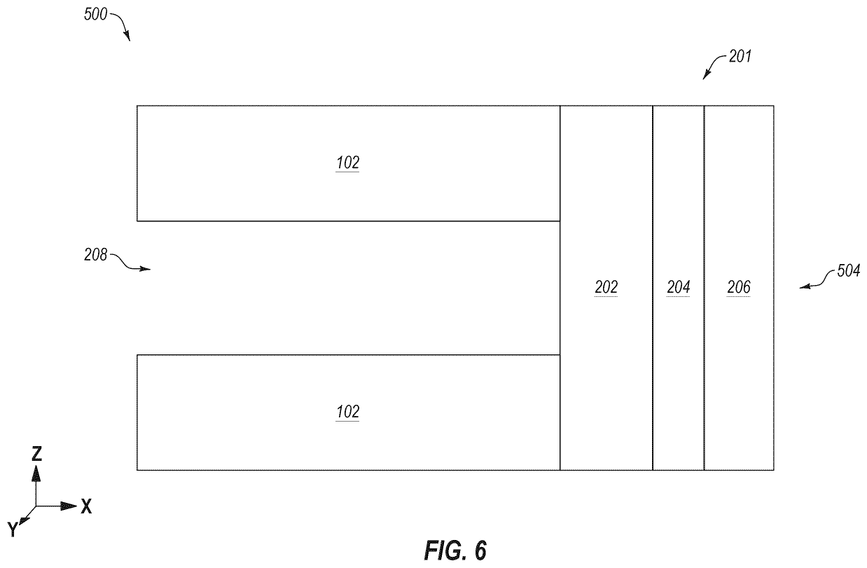

Referring next to FIG. 6, the cell pillar structures 201 (including the blocking dielectric material 202, the charge storage material, and the additional materials 206 thereof) previously described with reference to FIG. 2 may be formed to vertically extend through the preliminary stack structure 504, and then the levels of the sacrificial material 106 (FIG. 5) may be selectively removed to form the cavities 208 (e.g., void spaces).

As shown in FIG. 6, due to the omission of the shape memory material 104 (FIGS. 1 through 3B), the cavities 208 may respectively be defined by two levels of the insulative material 102 and outer side surfaces of the cell pillar structures 201 (e.g., outer side surfaces of the blocking dielectric material 202 thereof). For example, an individual cavity 208 may have an upper boundary at least partially defined by a lower surface of one level of the insulative material 102, a lower boundary at least partially defined by an upper surface of another level of the insulative material 102, and horizontal boundaries at least partially defined by outer side surfaces of the cell pillar structures 201.

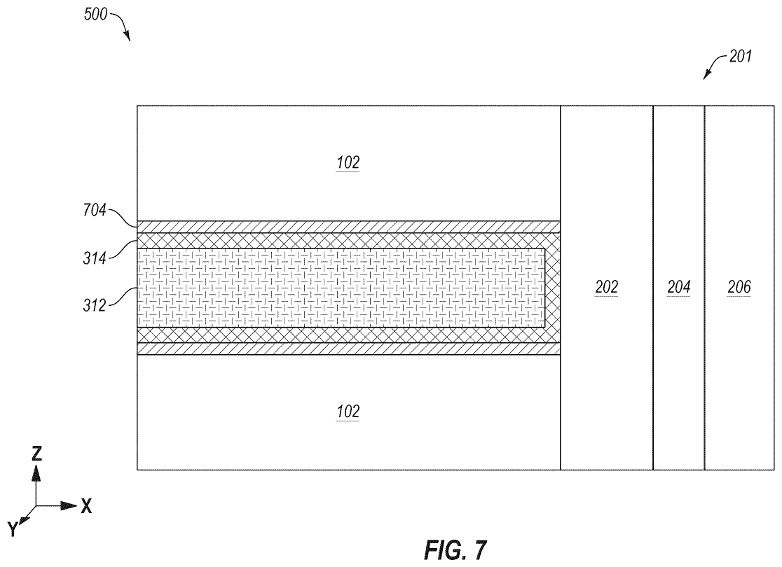

Referring next to FIG. 7, the cavities 208 (FIG. 2) may respectively be filled with shape memory material 704, as well as the conductive material 312, and, optionally, the liner material 314 previously described with reference to FIGS. 3A and 3B. The shape memory material 704 may be formed of and include one or more of the insulative shape memory materials previously described herein with reference to the shape memory material 104 (FIGS. 1 through 3B).

As shown in FIG. 7, within an individual cavity 208 (FIG. 6), two levels of the shape memory material 704 may be formed. One of the levels of the shape memory material 704 may be formed vertically over and in physical contact with a level of the insulative material 102 defining a lower boundary of the cavity 208 (FIG. 6), and an other of the levels of the shape memory material 704 may be formed vertically under and in physical contact with a level of the insulative material 102 defining a lower boundary of the cavity 208 (FIG. 6). In some embodiments, within an individual cavity 208 (FIG. 6), the shape memory material 704 formed (e.g., conformally formed) on exposed surfaces of the levels of the insulative material 102 and the cell pillar structures 201 defining boundaries of the cavity 208, and then portions of the shape memory material 704 on the surfaces (e.g., side surfaces) of the cell pillar structures 201 are removed (e.g., horizontally etched back) to form two discrete levels of the shape memory material 704 within the cavity 208 (FIG. 6). In additional embodiments, within an individual cavity 208 (FIG. 6), the shape memory material 704 is formed (e.g., conformally formed) on exposed surfaces of the levels of the insulative material 102 and the cell pillar structures 201 defining boundaries of the cavity 208, and portions of the shape memory material 704 on the surfaces (e.g., side surfaces) of the cell pillar structures 201 substantially maintained within the cavity 208 (FIG. 6). Following the formation of the shape memory material 704 within the cavities 208 (FIG. 6), the conductive material 312, and, optionally, the liner material 314, may be formed to substantially fill remaining portions of the cavities 208 (FIG. 6).

Thus, in accordance with embodiments of the disclosure, a method of forming a microelectronic device includes forming a preliminary stack structure having tiers vertically stacked relative to one another and respectively comprising insulative material and sacrificial material vertically neighboring the insulative material. Pillar structures respectively including semiconductor material are formed to vertically extend through the tiers of the preliminary stack structure. After forming the pillar structures, the sacrificial material of the tiers of the preliminary stack structure is selectively removed to form cavities. Respective ones of the cavities are partially filled with shape memory material. Remaining portions of the respective ones of the cavities are filled with conductive material.

The methods of the disclosure previously described herein may be employed to formed various microelectronic devices, including multi-deck (e.g., dual deck) memory devices (e.g., dual deck 3D NAND flash memory devices). For example, FIGS. 8 through 11 are simplified, partial vertical cross-sectional views illustrating a method of forming a microelectronic device (e.g., a multi-deck memory device, such as a multi-deck 3D NAND Flash memory device), in accordance with further embodiments of the disclosure. With the description provided below, it will be readily apparent to one of ordinary skill in the art that the methods and structures described herein may be used in various devices and electronic systems.

Referring to FIG. 8, a microelectronic device structure 800 may include a base structure 810, and a first preliminary stack structure 808 formed on or over the base structure 810. The first preliminary stack structure 808 may be considered a first (e.g., lower) preliminary deck for a multi-deck microelectronic device to be formed. The microelectronic device structure 800 also includes additional features (e.g., structures, materials, devices, regions), as described in further detail below.

The base structure 810 of the microelectronic device structure 800 may comprise a base material or construction upon which additional materials and structures of the microelectronic device structure 800 are formed. In some embodiments, the base structure 810 comprises a conductive structure formed of at least one electrically conductive material, such as one or more of a metal (e.g., tungsten (W), titanium (Ti), molybdenum (Mo), niobium (Nb), vanadium (V), hafnium (H), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductively-doped semiconductor material (e.g., conductively-doped polysilicon, conductively-doped germanium (Ge), conductively-doped silicon germanium (SiGe)), and a conductive metal-containing material (e.g., a conductive metal nitride, a conductive metal silicide, a conductive metal carbide, a conductive metal oxide). The base structure 810 may, for example, be employed as a source structure (e.g., a source plate) for a microelectronic device.

The first preliminary stack structure 808 may include tiers 812 vertically stacked relative to one another, and respectively including a level of insulative material 802, a level of shape memory material 804 on or over the level of insulative material 802, a level of sacrificial material 806 on or over the level of shape memory material 804, and an additional level of shape memory material 804 on or over the level of sacrificial material 806. The insulative material 802, the shape memory material 804, and the sacrificial material 806 of the tiers 812 of the first preliminary stack structure 808 may respectively be substantially similar to the insulative material 102, the shape memory material 104, and the sacrificial material 106 previously described herein with reference to FIGS. 1 through 3B.

The first preliminary stack structure 808 may include a desired quantity of the tiers 812. For example, the first preliminary stack structure 808 may include greater than or equal to eight (8) of the tiers 812, greater than or equal to sixteen (16) of the tiers 812, greater than or equal to thirty-two (32) of the tiers 812, greater than or equal to sixty-four (64) of the tiers 812, greater than or equal to one hundred and twenty-eight (128) of the tiers 812, greater than or equal to two hundred and fifty-six (256) of the tiers 812, or greater than or equal to five hundred and twelve (512) of the tiers 812.

The microelectronic device structure 800 may further include one or more contact structures 814. The contact structures 814 may, for example, serve as source contact structures. The contact structures 814 may be configured (e.g., sized, shaped, materially composed) and positioned to facilitate an electrical connection between one or more features (e.g., the base structure 810) of the microelectronic device structure 800 and one or more additional structures or devices (e.g., cell pillar structures, vertical strings of memory cells) to be formed on or over the contact structures 814, as described in further detail below. The contact structures 814 may individually be formed of and include at least one conductive material, such as a metal (e.g., W, Ti, Mo, Nb, V, Hf, Ta, Cr, Zr, Fe, Ru, Os, Co, Rh, Ir, Ni, Pd, Pt, Cu, Ag, Au, Al), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy, a steel, a low-carbon steel, a stainless steel), a conductively-doped semiconductor material (e.g., conductively-doped polysilicon, conductively-doped Ge, conductively-doped SiGe), a conductive metal-containing material (e.g., a conductive metal nitride, a conductive metal silicide, a conductive metal carbide, a conductive metal oxide), or combinations thereof. In some embodiments, the contact structures 814 are formed of and include W.

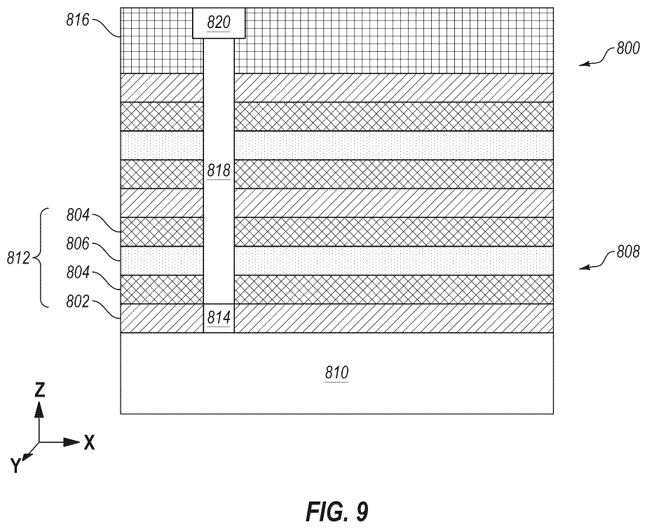

Referring next to FIG. 9, an interdeck dielectric material 816 may be formed on or over portions of the first preliminary stack structure 808. Thereafter, openings 818 (e.g., vias) may be formed to vertically extend through the interdeck dielectric material 816 and the first preliminary stack structure 808. As shown in FIG. 9, in some embodiments, the openings 818 vertically extend to and at least partially expose upper surfaces of the contact structures 814. Following the formation of the openings 818, plug structures 820 may be formed at upper vertical boundaries (e.g., in the Z-direction) of the openings 818 to substantially plug (e.g., cover) the openings 818.

The interdeck dielectric material 816 may be formed on or over exposed upper surfaces of the first preliminary stack structure 808. A material composition of the interdeck dielectric material 816 may be selected relative to material compositions of the levels of sacrificial material 806 of the first preliminary stack structure 808 such that the levels of sacrificial material 806 and the interdeck dielectric material 816 may be selectively removed relative to one another. The levels of sacrificial material 806 may be selectively etchable relative to the interdeck dielectric material 816 during common (e.g., collective, mutual) exposure to a first etchant, and the interdeck dielectric material 816 may be selectively etchable to the levels of sacrificial material 806 during common exposure to a second, different etchant. A material composition of the interdeck dielectric material 816 is different than material composition(s) of the levels of sacrificial material 806, and may comprise one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). A material composition of the interdeck dielectric material 816 may be selected to be substantially the same as a material composition of one or more (e.g., each) of the levels of insulative material 802 of the first preliminary stack structure 808, or may be selected to be different than material compositions of the levels of insulative material 802 of the first preliminary stack structure 808. In some embodiments, the interdeck dielectric material 816 is formed of and includes dielectric oxide material (e.g., SiOₓ, such as SiO₂). The interdeck dielectric material 816 may include a substantially homogeneous distribution of dielectric material, or a substantially heterogeneous distribution of dielectric material. In some embodiments, the interdeck dielectric material 816 exhibits a substantially homogeneous distribution of dielectric material. In additional embodiments, the interdeck dielectric material 816 exhibits a substantially heterogeneous distribution of dielectric material. The interdeck dielectric material 816 may, for example, be formed of and include a stack (e.g., laminate) of at least two different dielectric materials.

As shown in FIG. 9, the openings 818 may respectively vertically extend (e.g., in the Z-direction) through the interdeck dielectric material 816 and portions of the first preliminary stack structure 808 vertically underlying interdeck dielectric material 816 to one of the contact structures 814. Each of the openings 818 may be at least partially (e.g., substantially) horizontally aligned (e.g., in the X-direction and in the Y-direction) with one of the contact structures 814 vertically thereunder. Lower vertical boundaries of an individual opening 818 may be defined by surfaces (e.g., upper surfaces) of an individual contact structure 814, and horizontal boundaries of the opening 818 may be defined by surfaces (e.g., side surfaces) of the first preliminary stack structure 808 (e.g., surfaces of the levels of insulative material 802, the shape memory material 804, and the sacrificial material 806 of the tiers 812 thereof) and the interdeck dielectric material 816. The opening 818 may subsequently be filled with materials to form cell pillar structures (e.g., corresponding to the cell pillar structures 201 previously described herein with reference to FIG. 2) vertically extending through the microelectronic device structure 800, as described in further detail below.

Each of the openings 818 may individually be formed to exhibit a desired geometric configuration (e.g., a desired shape, and desired dimensions). In some embodiments, each of the openings 818 is individually formed to exhibit a columnar shape (e.g., a circular column shape, a rectangular column shape, an ovular column shape, a pillar shape), and is sized and positioned to expose a single (e.g., only one) contact structure 814. For example, each of the openings 818 may individually exhibit a circular column shape having a substantially circular horizontal cross-sectional area sized and positioned to at least partially (e.g., substantially) be located within a horizontal area of the contact structure 814 at least partially exposed thereby. In some embodiments, each of the openings 818 is substantially confined within a horizontal area of the contact structure 814 defining a lower vertical boundary of the opening 818. In additional embodiments, one or more of the openings 818 horizontally extends (e.g., in the X-direction and/or the Y-direction) past the horizontal area of the contact structure 814 defining a portion of a lower vertical boundary of the openings 818.

A desired quantity of the openings 818 may be formed in the microelectronic device structure 800. In some embodiments, a quantity of the openings 818 formed is the same as a quantity of the contact structures 814 within the microelectronic device structure 800. In additional embodiments, a quantity of the openings 818 formed is different than a quantity of the contact structures 814 within the microelectronic device structure 800. For example, a quantity of the openings 818 may be less than a quantity of the contact structures 814, such that less than all of the contact structures 814 are exposed by the openings 818.

With continued reference to FIG. 9, the plug structures 820 may respectively vertically extend (e.g., in the Z-direction) into the interdeck dielectric material 816 and may plug the openings 818. The plug structures 820 may be configured and positioned to protect the openings 818 from being filled with material during additional processing acts to form an additional preliminary stack structure over the interdeck dielectric material 816, as described in further detail below. Each of the plug structures 820 may be at least partially (e.g., substantially) horizontally aligned (e.g., in the X-direction and in the Y-direction) with one of the openings 818 vertically thereunder. Lower vertical boundaries of the plug structures 820 may be defined by upper vertical boundaries of remaining, unfilled portions of the openings 818 and horizontally extending surfaces of interdeck dielectric material 816 vertically above a lowermost vertical boundary of the interdeck dielectric material 816. The plug structures 820 may be confined within vertical boundaries (e.g., upper vertical boundaries, lower vertical boundaries) of the interdeck dielectric material 816. For example, the plug structures 820 may not vertically extend into portions of the first preliminary stack structure 808 vertically underlying the interdeck dielectric material 816. Horizontal boundaries of the plug structures 820 may be defined by vertically extending surfaces (e.g., side surfaces) of the interdeck dielectric material 816.

Each of the plug structures 820 may individually be formed to exhibit a desired geometric configuration (e.g., a desired shape, and desired dimensions) facilitating plugging (e.g., enclosing) at least one of the openings 818 thereunder. In some embodiments, each of the plug structures 820 is individually formed to exhibit a columnar shape (e.g., a circular column shape, a rectangular column shape, an ovular column shape, a pillar shape), and is sized and positioned to plug a single (e.g., only one) opening 818. For example, each of the plug structures 820 may individually exhibit a circular column shape having a substantially circular horizontal cross-sectional area sized and positioned to completely cover a horizontal cross-sectional area of the openings 818 plugged thereby. Each of the plug structures 820 may extend beyond horizontal boundaries of the openings 818 plugged thereby. In additional embodiments, one or more of the plug structures 820 may exhibit a different shape and/or a different size so long as the one or more of the plug structures 820 plug the openings 818 operatively associated therewith (e.g., within horizontal boundaries thereof).

The plug structures 820 may each individually be formed of and include at least one material able to bridge an upper portion of the opening 818 operatively associated therewith (e.g., plugged thereby) within the interdeck dielectric material 816, and able to protect a lower portion of the openings 818 within the first preliminary stack structure 808 from being filled with material during additional processing acts to form a second preliminary stack structure over the interdeck dielectric material 816. The plug structures 820 may, for example, comprise one or more of at least one semiconductive material (e.g., a silicon material, such as polysilicon), at least one conductive material (e.g., at least one metal, such as one or more of W, Ti, Mo, Nb, V, Hf, Ta, Cr, Zr, Fe, Ru, Os, Co, Rh, Ir, Ni, Pd, Pt, Cu, Ag, Au, and Al; at least one alloy, such as one or more of a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy, a steel, a low-carbon steel, and stainless steel; at least one conductive metal-containing material, such as one or more of a conductive metal nitride, a conductive metal silicide, a conductive metal carbide, and a conductive metal oxide; and at least one conductively doped semiconductor material, such as one or more of conductively doped silicon, conductively doped germanium, and conductively doped silicon-germanium), and at least one dielectric material (e.g., one or more of a dielectric oxide, a dielectric nitride, a dielectric oxynitride, and a dielectric carboxynitride). In some embodiments, the plug structures 820 are formed of and include polysilicon. In additional embodiments, the plug structures 820 are formed of and include tungsten (W). In further embodiments, the plug structures 820 are formed of and include titanium nitride (TiN).

The plug structures 820 may be formed using conventional processes (e.g., conventional material removal processes, such as conventional etching processes and conventional planarization processes; conventional deposition processes, such as conventional non-conformal deposition processes) and conventional processing equipment, which are not described in detail herein. By way of non-limiting example, following the formation of the openings 818, the interdeck dielectric material 816 may be subjected to an etching process to expand (e.g., increase) horizontal dimensions of upper portions of the openings 818 vertically positioned within the interdeck dielectric material 816; a plug material may be non-conformally formed inside and outside of the horizontally expanded, upper portions of the openings 818, and may bridge and close off the openings 818 without vertically extending into and filling portions of the openings 818 vertically below the interdeck dielectric material 816; and then portions of the plug material overlying upper vertical boundaries of the interdeck dielectric material 816 may be removed (e.g., by way of a planarization process, such as a CMP process) to form the plug structures 820.

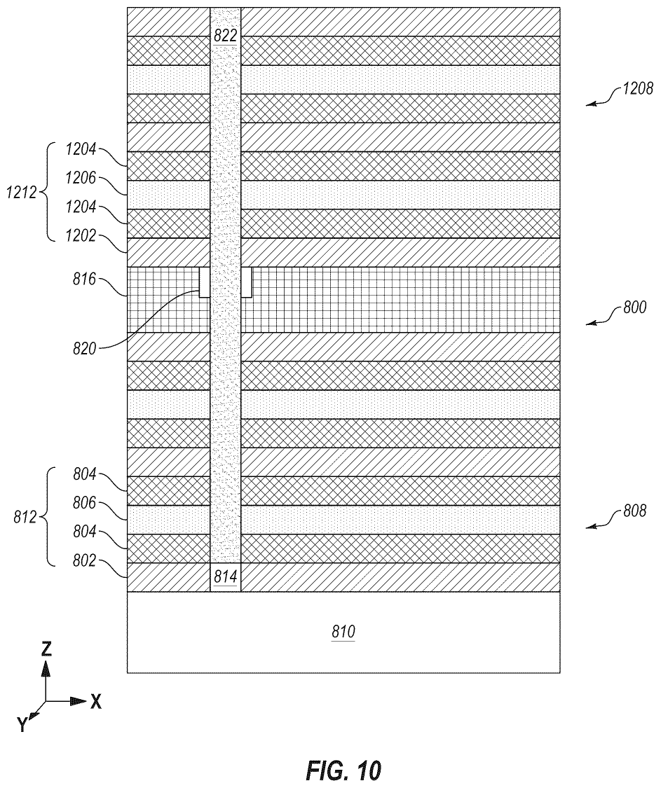

Referring next to FIG. 10, a second preliminary stack structure 1208 may be formed on or over the interdeck dielectric material 816 and the plug structures 820; and then cell pillar structures 822 may be formed to vertically extend through the second preliminary stack structure 1208, the plug structures 820, and the first preliminary stack structure 808. The second preliminary stack structure 1208 may be considered a second (e.g., upper) preliminary deck for a multi-deck microelectronic device to be formed.

The second preliminary stack structure 1208 may include additional tiers 1212 vertically stacked relative to one another, and respectively including a level of insulative material 1202, a level of shape memory material 1204 on or over the level of insulative material 1202, a level of sacrificial material 1206 on or over the level of shape memory material 1204, and an additional level of shape memory material 1204 on or over the level of sacrificial material 1206. The insulative material 1202, the shape memory material 1204, and the sacrificial material 1206 of the additional tiers 1212 of the second preliminary stack structure 1208 may respectively be substantially similar to the insulative material 102, the shape memory material 104, and the sacrificial material 106 previously described herein with reference to FIGS. 1 through 3B.

The second preliminary stack structure 1208 may include a desired quantity of the additional tiers 1212. For example, the second preliminary stack structure 1208 may include greater than or equal to eight (8) of the additional tiers 1212, greater than or equal to sixteen (16) of the additional tiers 1212, greater than or equal to thirty-two (32) of the additional tiers 1212, greater than or equal to sixty-four (64) of the additional tiers 1212, greater than or equal to one hundred and twenty-eight (128) of the additional tiers 1212, greater than or equal to two hundred and fifty-six (256) of the additional tiers 1212, or greater than or equal to five hundred and twelve (512) of the additional tiers 1212. A quantity of the additional tiers 1212 of the second preliminary stack structure 1208 may be equal to (e.g., the same as) a quantity of the tiers 812 of the first preliminary stack structure 808, or a quantity of the additional tiers 1212 of the second preliminary stack structure 1208 may be different than (e.g., less than, greater than) a quantity of the tiers 812 of the first preliminary stack structure 808.

Still referring to FIG. 10, the cell pillar structures 822 respectively may be formed to vertically extend from an upper boundary (e.g., an upper surface) of the second preliminary stack structure 1208 to upper boundaries of the contact structures 814. The cell pillar structures 822 may at least partially (e.g., substantially) land on and physically contact the contact structures 814. The cell pillar structures 822 may be formed to substantially fill remaining portions of the openings 818 vertically extending through the interdeck dielectric material 816 and the first preliminary stack structure 808, as well as additional openings formed to vertically extend through the second preliminary stack structure 1208 and the plug structures 820 to connect to the openings 818. Put another way, the cell pillar structures 822 may be formed to substantially fill relatively larger openings each individually formed from a combination of one of the openings 818, and an additional opening formed to vertically extend through the second preliminary stack structure 1208 and one of the plug structure 820 to an unfilled portion of the one of the openings 818.

The cell pillar structures 822 may each individually be formed of and include one or more materials facilitating the formation of vertical strings of memory cells for the microelectronic device structure 800 following subsequent processing (e.g., so-called “replacement gate” or “gate last” processing) of the microelectronic device structure 800, as described in further detail below. By way of non-limiting example, each of the cell pillar structures 822 may individually be formed to be substantially similar to the cell pillar structure 201 (including the blocking dielectric material 202, the charge storage material, and the additional materials 206 thereof) previously described with reference to FIG. 2.

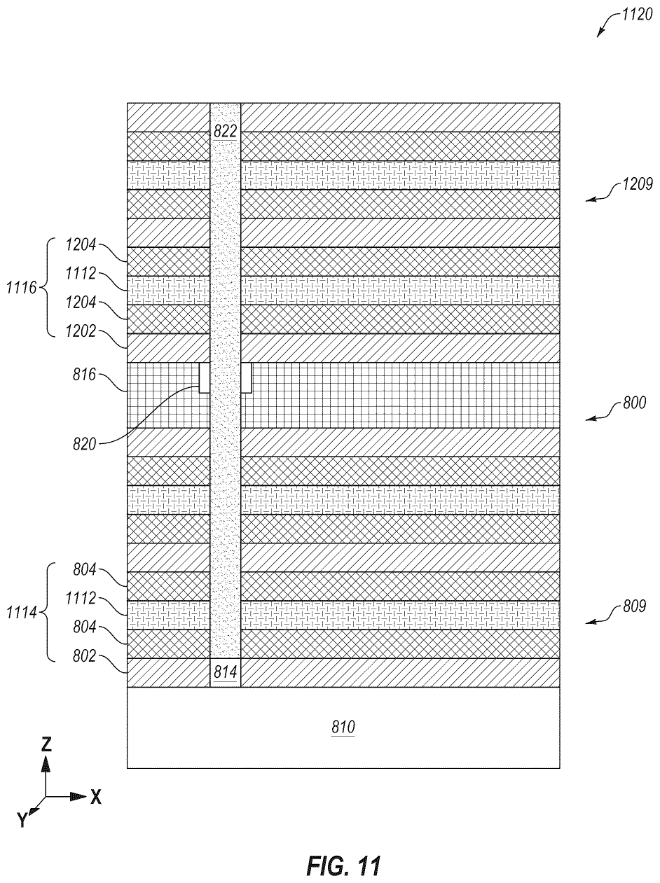

Referring next to FIG. 11, the microelectronic device structure 800, including the first preliminary stack structure 808 (FIG. 10) and the second preliminary stack structure 1208 (FIG. 10) thereof, may be subjected to so-called “replacement gate” or “gate last” processing acts to at least partially replace the levels of sacrificial material 806 of the tiers 812 (FIG. 10) of the first preliminary stack structure 808 (FIG. 10) and the levels of sacrificial material 1206 of the additional tiers 1212 (FIG. 10) of the second preliminary stack structure 1208 (FIG. 10) with levels of conductive material 1112 to form a microelectronic device 1120.

As shown in FIG. 11, the microelectronic device 1120 may include a first stack structure 809 (e.g., a first deck structure) formed from the first preliminary stack structure 808 (FIG. 10) and a second stack structure 1209 (e.g., a second deck structure) vertically overlying the first preliminary stack structure 808 (FIG. 10) and formed from the second preliminary stack structure 1208 (FIG. 10). The interdeck dielectric material 816 may be vertically interposed between the first stack structure 809 and the second stack structure 1209; and the cell pillar structures 822 may vertically extend through the first stack structure 809, the interdeck dielectric material 816, and the second stack structure 1209.

The first stack structure 809 of the microelectronic device 1120 may include tiers 1114 vertically stacked relative to one another, and respectively including a level of insulative material 802, a level of shape memory material 804 on or over the level of insulative material 802, a level of conductive material 1112 on or over the level of shape memory material 804, and an additional level of shape memory material 804 on or over the level of conductive material 1112. The conductive material 1112 of the tiers 1114 of the first stack structure 809 may be substantially similar to the conductive material 312 previously described herein with reference to FIGS. 3A and 3B.

The second stack structure 1209 of the microelectronic device 1120 may include additional tiers 1116 vertically stacked relative to one another, and respectively including a level of insulative material 1202, a level of shape memory material 1204 on or over the level of insulative material 1202, a level of conductive material 1112 on or over the level of shape memory material 1204, and an additional level of shape memory material 1204 on or over the level of conductive material 1112. The conductive material 1112 of the additional tiers 1116 of the second stack structure 1209 may be substantially similar to the conductive material 312 previously described herein with reference to FIGS. 3A and 3B.

Thus, in accordance with embodiments of the disclosure, a microelectronic device includes a stack structure having tiers vertically stacked relative to one another, and pillar structures respectively including semiconductor material vertically extending through the tiers of the stack structure. The tiers of the stack structure respectively include insulative material, shape memory material vertically neighboring the insulative material, and conductive material vertically neighboring the shape memory material.

The methods and structures of the disclosure incorporate levels of insulative shape memory materials within one or more stack structures (e.g., decks) of a microelectronic device. These levels of insulative shape memory material are designed to alter their shape in response to temperature fluctuations, effectively mitigating the problem of tier deflection. The methods and structures of the disclosure may also mitigate stiction by increasing a strength and/or rigidity of levels insulative material of one or more stack structures of a microelectronic device of the disclosure. Mitigating tier deflection and stiction may facilitate reducing the thickness of tiers of the stack structure. Reducing the thickness of the tiers may permit a feature density of the microelectronic device to increase relative to conventional microelectronic device configurations. Increasing a feature density of the microelectronic device may facilitate the fabrication of relatively smaller microelectronic devices, which in turn may reduce the space needed for the microelectronic devices in associated electronic devices and systems. Similarly, increasing the feature density of the microelectronic device may facilitate relatively greater power and memory functionality per unit area. Relatively enhanced power and memory functionality may permit microelectronic devices and electronic systems of the disclosure to have enhanced performance, relative to conventional microelectronic devices and conventional electronic systems, without an increase in size. Furthermore, mitigating tier deflection and stiction in a microelectronic device may reduce the number of failed microelectronic devices during and/or soon after production. Reducing the number of failures may increase the efficiency of the production of the microelectronic devices, which may result in relatively reduced costs.

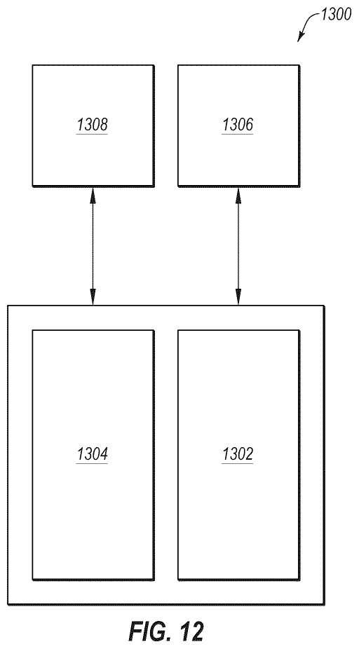

Microelectronic devices (e.g., the microelectronic device 1120 (FIG. 11)) and microelectronic device structures (e.g., the microelectronic device structures 100 (FIGS. 3A and 3B), 400 (FIG. 4A), 406 (FIG. 4B), 500 (FIG. 7), 800 (FIG. 11)), in accordance with embodiments of the disclosure, may be used in embodiments of electronic systems of the disclosure. For example, FIG. 12 is a block diagram illustrating an electronic system 1300 according to embodiments of disclosure. The electronic system 1300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 1300 includes at least one memory device 1302. The memory device 1302 may comprise, for example, one or more of a microelectronic device (e.g., the microelectronic device 1120 (FIG. 11)) and a microelectronic device structure (e.g., one of the microelectronic device structures 100 (FIGS. 3A and 3B), 400 (FIG. 4A), 406 (FIG. 4B), 500 (FIG. 7), 800 (FIG. 11)) previously described herein. The electronic system 1300 may further include at least one electronic signal processor device 1304 (often referred to as a “microprocessor”). The electronic signal processor device 1304 may, optionally, comprise one or more of a microelectronic device (e.g., the microelectronic device 1120 (FIG. 11)) and a microelectronic device structure (e.g., one of the microelectronic device structures 100 (FIGS. 3A and 3B), 400 (FIG. 4A), 406 (FIG. 4B), 500 (FIG. 7), 800 (FIG. 11)) previously described herein. While the memory device 1302 and the electronic signal processor device 1304 are depicted as two (2) separate devices in FIG. 12, in additional embodiments, a single (e.g., only one) memory/processor device having the functionalities of the memory device 1302 and the electronic signal processor device 1304 is included in the electronic system 1300. In such embodiments, the memory/processor device may include one or more of a microelectronic device (e.g., the microelectronic device 1120 (FIG. 11)) and a microelectronic device structure (e.g., one of the microelectronic device structures 100 (FIGS. 3A and 3B), 400 (FIG. 4A), 406 (FIG. 4B), 500 (FIG. 7), 800 (FIG. 11)) previously described herein. The electronic system 1300 may further include one or more input devices 1306 for inputting information into the electronic system 1300 by a user, such as, for example, a mouse or other pointing device, a keyboard, a touchpad, a button, or a control panel. The electronic system 1300 may further include one or more output devices 1308 for outputting information (e.g., visual or audio output) to a user such as, for example, a monitor, a display, a printer, an audio output jack, a speaker, etc. In some embodiments, the input device 1306 and the output device 1308 comprise a single touchscreen device that can be used both to input information to the electronic system 1300 and to output visual information to a user. The input device 1306 and the output device 1308 may communicate electrically with one or more of the memory device 1302 and the electronic signal processor device 1304.

The structures, devices, systems, and methods of the disclosure advantageously facilitate one or more of improved microelectronic device performance, reduced costs (e.g., manufacturing costs, material costs), increased miniaturization of components, and greater packaging density as compared to conventional structures, conventional devices, conventional systems, and conventional methods. The structures, devices, systems, and methods of the disclosure may also improve scalability, efficiency, and simplicity as compared to conventional structures, conventional devices, conventional systems, and conventional methods.

The embodiments of the disclosure described above and illustrated in the accompanying drawing figures do not limit the scope of the invention, since these embodiments are merely examples of embodiments of the invention, which is defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

What is claimed is:

1. A microelectronic device, comprising:
a stack structure having tiers vertically stacked relative to one another and respectively comprising:
insulative material;
shape memory material vertically neighboring the insulative material; and
conductive material vertically neighboring the shape memory material; and
pillar structures respectively including semiconductor material vertically extending through the tiers of the stack structure.

2. The microelectronic device of claim 1, wherein the shape memory material of respective ones of the tiers of the stack structure comprises one or more of a shape memory oxide material, a shape memory ceramic material, and a shape memory alloy material.

3. The microelectronic device of claim 1, wherein the shape memory material of respective ones of the tiers of the stack structure comprises one or more of VO₂, VMoO₂, and VWO₂.

4. The microelectronic device of claim 1, wherein the shape memory material of respective ones of the tiers of the stack structure comprises one or more of BiFeO₃, BaTiO₃, CeO₂—ZrO₂, CeO₂—Y₂O₃, CeO₂—ZrO₂.

5. The microelectronic device of claim 1, wherein the shape memory material of respective ones of the tiers of the stack structure comprises one or more of CuAlNi and NiTi.

6. The microelectronic device of claim 1, the tiers of the stack structure further comprise additional shape memory material, the conductive material vertically interposed between the shape memory material and the additional shape memory material.

7. The microelectronic device of claim 1, wherein the conductive material of respective ones of the tiers of the stack structure comprises Mo.

8. The microelectronic device of claim 1, wherein the tiers of the stack structure further comprise a liner material substantially surrounding the conductive material, a portion of the liner material vertically interposed between the conductive material and the shape memory material.

9. The microelectronic device of claim 8, wherein the liner material comprises one or more of VO₂, VMoO₂, and Al₂O₃.

10. A method of forming a microelectronic device, comprising:
forming a preliminary stack structure having tiers vertically stacked relative to one another and respectively comprising:
insulative material;
shape memory material vertically neighboring the insulative material; and
sacrificial material vertically neighboring the shape memory material;
forming pillar structures respectively including semiconductor material to vertically extending through the tiers of the preliminary stack structure; and
replacing the sacrificial material of the tiers of the preliminary stack structure with conductive material after forming the pillar structures.

11. The method of claim 10, further comprising selecting the shape memory material to comprise at least one shape memory oxide material.

12. The method of claim 10, further comprising selecting the shape memory material to comprise VO₂, VMoO₂, and VWO₂.

13. The method of claim 10, further comprising:
selecting the insulative material to comprise dielectric oxide material; and
selecting the sacrificial material to comprise dielectric nitride material.

14. The method of claim 10, further comprising selecting the conductive material to comprise Mo.

15. The method of claim 10, wherein replacing the sacrificial material of the tiers of the preliminary stack structure with conductive material comprises:
selectively removing the sacrificial material of the tiers of the preliminary stack structure to form cavities;
conformally forming liner material within the cavities; and
forming the conductive material on the liner material within the cavities.

16. A method of forming a microelectronic device, comprising:
forming a preliminary stack structure having tiers vertically stacked relative to one another and respectively comprising:
insulative material;
sacrificial material vertically neighboring the insulative material;
forming pillar structures respectively including semiconductor material to vertically extending through the tiers of the preliminary stack structure;
after forming the pillar structures, selectively removing the sacrificial material of the tiers of the preliminary stack structure to form cavities;
partially filling respective ones of the cavities with shape memory material; and
filling remaining portions of the respective ones of the cavities with conductive material.

17. The method of claim 16, wherein partially filling respective ones of the cavities with shape memory material comprises forming one or more of VO₂, VMoO₂, and VWO₂ within the respective ones of the cavities.

18. The method of claim 16, wherein partially filling respective ones of the cavities with shape memory material comprises physically contacting the pillar structures and the insulative material of respective ones of the tiers with the shape memory material.

19. The method of claim 16, wherein filling remaining portions of the respective ones of the cavities with conductive material comprises:
conformally forming liner material within the respective ones of the cavities, the liner material comprising one or more of Al₂O₃, VO₂, VMoO₂, and VWO₂; and
forming the conductive material on the liner material within the respective ones of the cavities.

20. The method of claim 19, further comprising selecting the conductive material to comprise one or more of Mo and W.
